(19) United States
(12) Patent Application Publication
(10) Pub. No.: US 2024/0274895 A1
(43) Pub. Date: Aug. 15, 2024

(54) METHOD OF MAKING A BATTERY SENSOR

(71) Applicant: Xin HE, Baotou (CN)

(72) Inventor: Xin HE, Baotou (CN)

(21) Appl. No.: 18/568,275

(22) PCT Filed: Apr. 21, 2022
(86) PCT No.: PCT/CN2022/088302

§ 371 Date: Dec. 8, 2023

(30) Foreign Application Priority Data
Jun. 8, 2021 (CN) 202110637482.1

(51) Int. Cl. H01M 10/42; H01M 10/48; H05K 3/00; H05K 3/06; H05K 3/12; H05K 3/16; H05K 3/28

(52) U.S. Cl. CPC H01M 10/425; H01M 10/48; H05K 3/0026; H05K 3/0047; H05K 3/064; H05K 3/125; H05K 3/16; H05K 3/284; H05K 2203/107

(57) ABSTRACT

A method for making a battery sensor is provided. Firstly, when the surface layer of battery case is insulated, a circuit pattern layout is carried out on the surface layer of the battery case, wherein the circuit pattern layout includes a base circuit layout and a sensor layout; conductive lines are fabricated in the surface layer of the battery case based on the base circuit layout, wherein the pattern of the conductive lines is the same as the circuit pattern; and sensors are fabricated in the surface layer of the battery case based on the sensor layout, wherein the sensors are the same as the sensor layout diagram.

### CROSS-REFERENCE TO THE RELATED APPLICATIONS

This application is the national phase entry of International Application No. PCT/CN2022/088302, filed on Apr. 21, 2022, which is based upon and claims priority to Chinese Patent Application No. 202110637482.1, filed on Jun. 8, 2021, the entire contents of which are incorporated herein by reference.

### TECHNICAL FIELD

The present application relates to the technical field of battery sensor, and specifically to a method of making battery sensor.

### BACKGROUND

Currently, the number of electrical devices is gradually increasing, and the use of batteries is widespread. For example, portable electronic devices, electric vehicles, ships, and electric aircraft are all powered by batteries. In order to ensure the battery safety, a plurality of temperature sensors is commonly used to monitor the operating condition of battery.

The most common way is to directly insert a sensor at the bottom of package or between the cell units, however, this strategy increases the size of battery, and the distance between sensor and battery is long which does not fit tightly, so there are the issue of detecting errors and low accuracy when it monitors the state of battery; this implementation setup only applicable for sensor with simple structures, whereas the types and number of sensors are limited, resulting the battery management system hard to determine the state of battery more accurately in accordance with multiple data types and data points.

In summary, existing battery sensors suffer from the issues of increased size, low accuracy, and incomplete data information.

### SUMMARY

The object of present application is to provide a method for making a battery sensor, which able to solve the problems of battery with increased size by sensors, limited space for multiple different kinds of sensor layouts, fewer data points and lower accuracy.

In order to realize the above purposes, the technical solutions adopted in the embodiments of the present application are as follows:

In the first aspect, embodiments of the present application provide a method of making battery sensor, wherein method comprising:
When the surface layer of battery case is insulating, a circuit pattern layout is performed in the surface layer of battery case, wherein the circuit pattern layout includes a base circuit layout and a sensor layout;
Making conductive lines in the surface layer of battery case based on the base circuit layout, wherein the conductive lines have same pattern as base circuit layout and wherein sensor is connected to conductive lines;
Making sensors in the surface layer of battery case based on the sensor layout, wherein sensors are positioned in the same location as sensor layout.

Optionally, prior to the step of making conductive lines in the surface layer of battery case based on base circuit layout, wherein method further comprises:
directly utilize ablation technique with nanosecond, picosecond or femtosecond laser, or a process of coating the surface layer of battery case with light-absorbing material and then utilizing nanosecond, picosecond or femtosecond laser for ablation, or a process of exposing and etching a masked version on the surface layer of battery case, or a process of covering the surface layer of battery case with a photoresist and then utilizing a process of exposure and etching a masked version of the surface of the battery case, or a process of directly utilizing a process of mechanical etching or imprinting, making circuit pattern recesses based on the circuit pattern layout on the surface layer of battery case; etching a corresponding target space on the surface layer of battery case according to the sensor layout;
The step of making conductive lines in the surface layer of battery case based on base circuit layout comprises:
Make conductive lines within circuit pattern recesses;
The step of making a sensor in the surface layer of battery case based on sensor layout comprises:
Make sensors in the target space.

Optionally, the step of making circuit pattern recesses in the surface layer of battery case based on the circuit pattern layout; and etching a corresponding target space in the surface layer of battery case based on sensor layout comprises:
After making conductive lines within the circuit pattern recesses, etching out the corresponding target space; or
Making conductive lines while etching out a corresponding target space, and the conductive lines are partially overlaying with the target space; or
Making conductive lines while etching out a corresponding target space and filling the target space with colloid.

Optionally, prior to the step of making conductive lines in the surface layer of battery case based on base circuit layout, wherein method further comprises:
When the surface layer of battery case is conducting, groove in the surface layer of battery case to form a slot;
Depositing an insulating layer on the bottom of slot;
Circuit patterning on the insulating layer, wherein the circuit patterning comprises a base circuit layout and sensor layout; or
An insulating layer is made on the surface layer of battery case;
Circuit patterning on the insulating layer, wherein the circuit patterning comprises a base circuit layout and sensor layout.

Optionally, the step of making conductive lines in the surface layer of battery case based on base circuit layout comprises:
Utilizing a vacuum plasma sputtering process, the electrically conductive lines are fabricated in the surface layer of battery case according to the pattern of mask.

Optionally, step of making conductive lines in the surface layer of battery case based on base circuit layout comprises:
The conductive lines on the surface layer of battery case are made via inkjet printing, or dispensing, or screen-printing process with metal-ion solution; or the vapor depositing process with the circuit pattern mask to plate conductive lines on the surface layer of battery case.

Optionally, after the step of fabricating sensor on the surface layer of battery case based on sensor layout, wherein method further comprises: coating a liquid isolating material onto the surface of conductive line and sensor, to form a solid isolating layer.

Optionally, the sensors include liquid sensor and gas sensor, prior to the step of making a sensor on surface layer of battery case based on sensor layout, wherein method further comprises:
Utilizing a laser drilling to drill holes in accordance with the sensor layout, so that sensors are located in the same position as sensor layout;
Following the step of making sensor in the surface layer of battery case based on sensor layout, wherein method further comprises:
Encapsulation is directly carried out on the surface of sensor; or the surface layer of a multilayer sensor is directly used as the encapsulation layer; wherein the liquid sensor is used for electrolyte leakage monitoring, whereas the surface barrier layer of the liquid sensor is made of hydrophobic pro-electrolyte material; gas sensor is used for gas leakage monitoring, and the surface barrier layer of the sensor is made of hydrophobic porous material.

Optionally, prior to the step of making conductive lines in the surface layer of battery case based on base circuit layout, wherein method further comprises:
Making a polymer transition layer based on base circuit layout and sensor layout;

The step of making conductive lines in the surface layer of battery case based on base circuit layout comprises:
Making conductive lines based on transition layer;

The step of making a sensor in the surface layer of battery case based on sensor layout comprises:
Making sensor based on the transition layer.

In the second aspect, embodiments of the present application also provide a method of making a battery sensor, utilizing sensor in battery package, battery package comprising a plurality of battery units with a separating layer provided between two adjacent battery units; wherein method comprising:
When the surface layer of battery case is insulating, a circuit pattern layout is carried out in the surface layer of battery case which adjacent to the separating layer, wherein the circuit pattern layout includes a base circuit layout and a sensor layout;
Fabricate conductive lines in the adjacent location between the surface layer of battery case and the separating layer based on base circuit layout, wherein conductive lines have the same pattern as base circuit layout and sensor is connected to conductive lines.

A sensor is made in the surface layer of battery case which adjacent to a separating layer based on sensor layout, wherein the sensor is positioned in the same location as sensor layout, and sensor is connected to conductive line;
Encapsule the surface of fabricated battery case, and then laminate to the separating layer.

In a third aspect, embodiments of the present application also provide a battery sensor fabrication method applied to fabricate sensor for battery package, the battery package includes cell units, whereas the cell unit further comprising substrate, and the method comprising:
Performing a circuit pattern layout on the substrate, wherein aid circuit pattern layout includes a base circuit layout and a sensor layout;
Making conductive lines on the substrate based on base circuit layout, wherein the conductive lines have the same pattern as base circuit layout;
Making sensor on the substrate based on sensor layout, wherein the sensor is positioned in the same location as sensor layout, and the sensor is connected to the conductive lines;
Laminate the substrate to the surface of cell unit.

The present application provides a method for making battery sensor, firstly when the surface battery case is insulating, a circuit pattern layout is made in the surface layer of battery case, wherein the circuit pattern layout comprises a base circuit layout and a sensor layout; conductive line is made in the surface layer of battery case in accordance with the base circuit layout, wherein the conductive line is made with the same pattern as the base circuit layout; a sensor is made in accordance with the sensor layout and fabricated in the surface of the battery case, wherein the sensor is the same as the sensor layout, and wherein sensor is connected to conductive lines. Since the method provided in the present application directly makes sensor on the surface layer of battery case, the sensor is close contact with the battery, and the accuracy is higher when detecting the state of the battery. In addition, since the layout is directly in the surface layer of the battery case, the space occupied is reduced and there is no significantly increasing on the size as well as the weight of battery. At the same time, the monitoring sensor can be applied to a wide range of battery models and can be iteratively updated as the manufacturing process is upgraded.

In order to make the above objects, features, and advantages of the present application more obvious and understandable, the following embodiments, together with the attached drawings, are described in detail as follows.

### BRIEF DESCRIPTION OF THE DRAWINGS

In order to more clearly illustrate the technical solutions for the embodiments of present application, the accompanying drawings that need to be used in the embodiments will briefly introduced in following part, and it should mention that the following drawings only show certain embodiments of the present application, thus should not be regarded as a limitation for the scope, and for the ordinary technicians in the field, other related drawings can be obtained according to these drawings without creative contribution.

FIG. 1 shows the first flowchart for the method to making a battery sensor provided by embodiments of present application.

FIG. 2 shows the second flowchart for the method of making a battery sensor provided by embodiments of present application.

FIG. 3 shows the third flowchart for the method of making a battery sensor provided by embodiments of present application.

FIG. 4 shows the fourth flowchart for the method of making a battery sensor provided by embodiments of present application.

FIG. 5 shows the fifth flowchart for the method of making a battery sensor provided by embodiments of present application.

FIG. 6 shows a schematic diagram for the cross-section of a cell unit provided by embodiments of present application.

FIG. 7 shows the sixth flowchart for the method of making a battery sensor provided by embodiments of present application.

FIG. 8 shows the seventh flowchart for the method of making a battery sensor provided by embodiments of present application.

### DETAILED DESCRIPTION OF THE EMBODIMENTS

In order to make the purposes, technical solutions, and advantages of the embodiments of the present application clearer, the technical solutions in the embodiments of present application are clearly and completely described later in conjunction with the drawings in the embodiments of present application. Apparently, the embodiments depicted are only a portion of the embodiments of present application, and not all of the embodiments. Generally, the components for embodiments of present application described and illustrated in the accompanying drawings herein may be arranged and designed in a variety of different configurations.

Accordingly, the following detailed description for embodiments of the present application provided in the accompany drawings is not intended to limit the claimed scope, but rather represents only selected embodiments of present application. Based on the embodiments in present application, all other embodiments obtained by ordinary researchers in the art without creative labor, belong to the protecting scope of present application.

It should be noted that similar symbols and letters represent similar item in the following drawings, and therefore, once an item is defined in one drawing, it does not need to be further defined or explained in subsequent drawings. Meanwhile, in the description of the present application, the term of “first” and “second” etc., are used only to differentiate descriptions, and should not to be construed as indicating or implying a relative importance.

It should be mentioned that in this document, relational terms like the first and the second are used only to distinguish one entity or operation from another, and do not necessarily require or imply the existence of any such actual relationship or order between these entities or operations. Furthermore, the term of “including”, “comprising”, or any other variant thereof are intended to cover non-exclusive inclusion, thus comprising a set of elements for a process, method, item or equipment which not only contains those elements, but also other elements not expressly listed, or other elements that are inherent to such process, method, item or equipment. Without further limitation, the fact that an element is defined by the phrase “includes a . . . ” does not preclude the existence of additional identical elements in the process, method, article or apparatus that includes similar element.

In the description of the present application, it is noted that the terms “up”, “down,” “inside”, “outside,” etc., indicate an orientation or position. The terms “up”, “down”, “inside”, “outside”, etc. are indicative of an orientation or position. The placement relationships are based on the orientation or positional relationships shown in the accompanying drawings, or the orientation or positional relationships in which the products of the application are customarily placed when in use, and are intended only to facilitate the description of the application and to simplify the description, and are not intended to indicate or imply that the devices or elements referred to must have a particular orientation, be constructed and operated with a particular orientation, and therefore are not to be construed as a limitation of the application.

In the description of present application, it should also be mentioned that the term of “setting”, “connecting” should be understood as the broad sense, unless otherwise expressly specified and qualified, e.g., it may be a fixed connection, a detachable connection, or an integrally connection; it can be mechanical connected or electrical connected; it can be directly connected or indirect connected through an intermedia medium, and it can be a connection within the two components. For the ordinary technician in this field, could understand the specific meaning in specific cases from the above terms for present application.

Some embodiments of the present application are described in detail according to the accompanying drawings. Under the circumstance without conflict, the following embodiments and features in the embodiments may be combined with each other.

As described in the background technique, the sensors are currently generally re-set separately after the circuit package is completed, on one hand, inevitably leads to an increase in the occupied spaces, and on the other hand, the accuracy of detection of the sensor is relatively low due to the distance between sensors and cell body.

Accordingly, in order to solve the above problems, the present application provides a method for making a battery sensor, which achieves the effect of improving the accuracy of the sensor and reducing the size of the battery by making the sensor in the surface layer of the battery case.

The following is an exemplary description of the method of making a battery sensor provided in the present application:

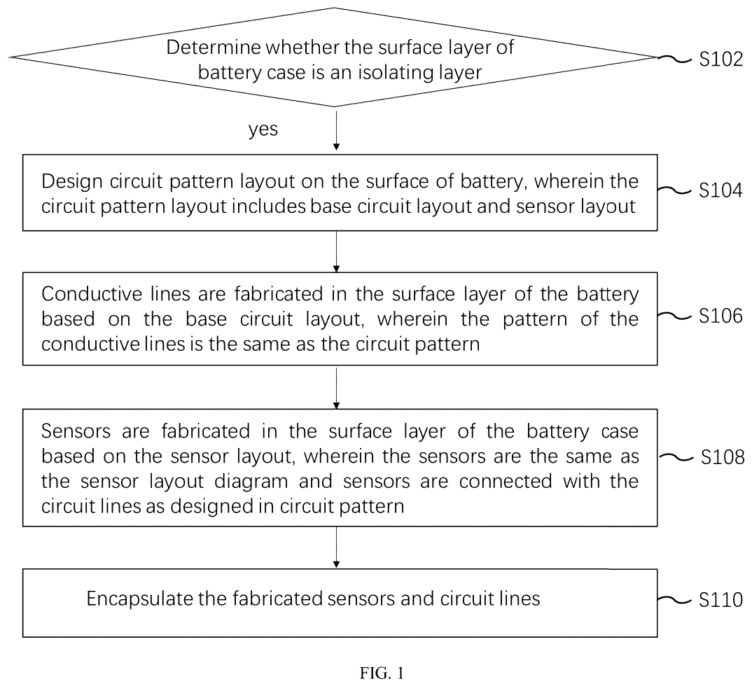

As an implementation, referring to FIG. 1, the method of making the battery sensor comprises:
S102, determining whether the surface layer of battery case is an insulating layer, and if so, executing S104.
S104, a circuit pattern layout is performed on the surface layer of battery case, wherein the circuit pattern layout includes a base circuit layout with a sensor layout.
S106, conductive lines are fabricated in the surface layer of battery case based on the base circuit layout, wherein the conductive lines have the same pattern as the base circuit layout.
S108, making a sensor on the surface of the battery case based on the sensor layout, wherein the sensor is positioned in the same location as the sensor layout diagram and wherein the sensor is connected to the conductive line.

It should be noted that the current generally commercialized batteries include cylinder cell, prismatic cell, and pouch cell, wherein the above surface layer of battery case may be an insulating layer or a conductive layer, for example, when the surface layer of battery case is made of an aluminum-plastic film, the surface layer of battery case is an insulating layer, and thus does not affect the normal operation of the sensor after the sensor is made.

Optionally, in determining that the surface layer of battery case is an insulating layer, the layout for the circuit pattern on the surface of the battery can be carried out first, and as an implementation, the circuit pattern layout as described in present application could draw lines on the surface of the battery, i.e., to carry out the circuit design on the surface of the battery in order to fabricate the sensors in a subsequent process.

It is to be understood that the circuit pattern layout described in the present application comprises a base circuit layout and a sensor layout, wherein the base circuit layout and the wiring layout of the sensor are laid out so as to enable the subsequent fabrication of the sensor more quickly, and of course, the base circuit layout is connected to the sensor layout, so as to enable the sensors to work efficiently after the sensor has been fabricated. In other words, the circuit pattern layout actually prepares the subsequent process.

As an implementation, after fabricating the conductive lines and sensors, they can be selectively encapsulated, i.e., the entire battery sensor can be encapsulated or not encapsulated, there is no limitation herein.

When the battery sensor needs to be encapsulated, after S108, the method further comprises:
S110, encapsulate the fabricated sensor with the conductive line.

In other words, after the process of circuit pattern layout, the conductive lines and sensors can be made on battery surface according to the basic circuit layout and sensor layout, respectively, and finally by encapsulating them, all these could achieve the sensors fabrication on the battery surface. For the sake of illustration, these words are used as an example of packaging the completed sensor and conductive line.

With this realizing process, it is possible to make a sensor directly on the surface of the battery, which enables a more accurate detection of the battery state due to the direct contact of the sensor with the battery surface and, furthermore, makes the sensor and the battery smaller, which facilitates miniaturization.

At the same time, when the cells are assembled as a battery package, a separating layer is required between two adjacent cells to exclude mutual interference, so when the sensor and the conductive line are encapsulated, the material of the separation layer can be used directly for encapsulation, which in turn allows the encapsulation layer to be used as a separating layer and facilitates miniaturization.

It should be noted that the present application does not limit the material of the conductive line, which may be, for example, a metallic material, a conductive carbon material.

It should also be noted that the conductive line described in the present application may refer to a wire used to connect the sensor to the associated circuitry, or may refer to a circuitry including electronics, and the conductive line may be provided with an anti-overcurrent resistor, which is connected to the sensor.

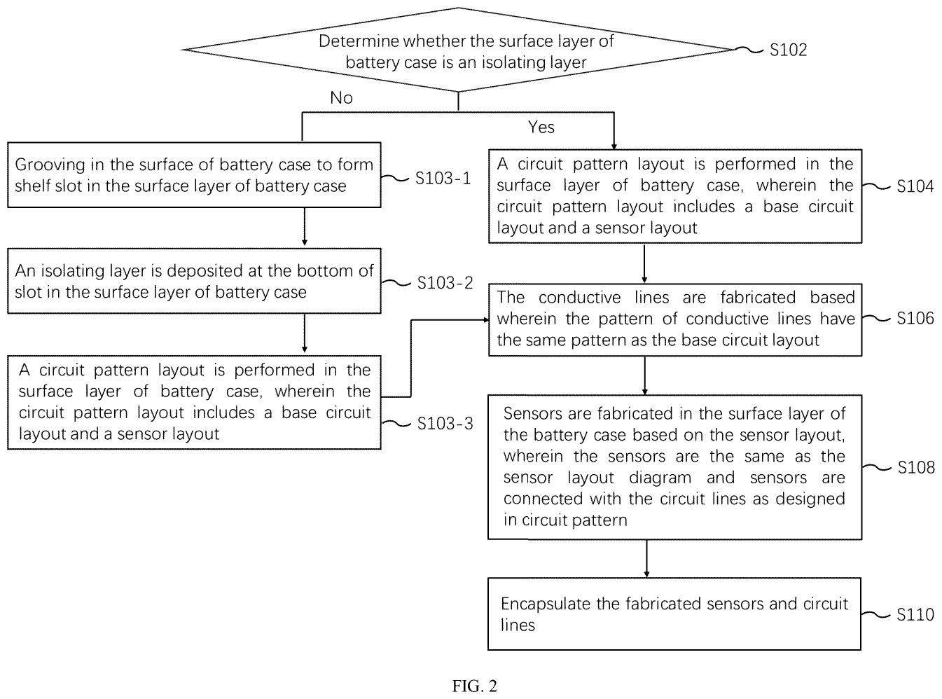

Furthermore, as an implementation, referring to FIG. 2, when the surface layer of battery case is judged to be a noon-insulating layer, it is executed:
S103—1, a grooving process is performed on the surface layer of the battery case to form a slot in the surface layer of the battery case.
S103—2, depositing an insulating layer on the bottom of the slots.
S103—3, a circuit pattern layout is performed on the insulating layer, wherein the circuit pattern layout includes a base circuit layout with a sensor Layout.

When the surface layer of battery case is electrical conducting, if the sensor is directly fabricated on it, the sensor circuit is shorted and the sensor does not work. Therefore, when the surface layer of battery case is conducting, it needs to be insulated first.

First, a grooving process is performed on the surface layer of the battery case to form a placement slot in the surface layer of the battery case, which is mainly used for placing sensors and related conductive lines, and then an insulating layer, such as an insulating colloidal layer, is deposited at the bottom of the placement slot, which in turn allows for a circuit mass layout on the insulating layer. The subsequent production of the sensor process and the battery shell surface layer for the insulating layer of the process is consistent, will not be repeated here.

Of course, in an optional realization, when the surface layer of battery case is a conducting layer, an insulating layer can also be made on the surface layer of battery case, and then a circuit pattern layout can be made on the insulating layer, wherein the circuit pattern layout includes a base circuit layout with a sensor layout.

Wherein the insulating layer, as described in the present application, can be a flat layer on the surface layer of the battery case, or can be only a layer laid out in the same layer as circuit pattern, and the conductive lines are laid out on the insulating layer.

Of course, when the surface of the battery case is insulating, it is also possible to groove the surface layer of the battery case, and after forming the placement slot, lay out the circuit pattern inside the placement slot, and there is no further limitation here.

For the sake of convenient illustration, this application explains the battery sensor producing method using an insulated battery surface as an example.

To ensure better fabrication effect for the sensors, prior to lay out the circuit patterning, the method may also include:
Clean the surface of the battery case.

As an optional realizing approach, the surface can be cleaned by using deionized water or the organic solvent ethanol, and then cleaned with plasma under vacuum or UV (Ultraviolet).

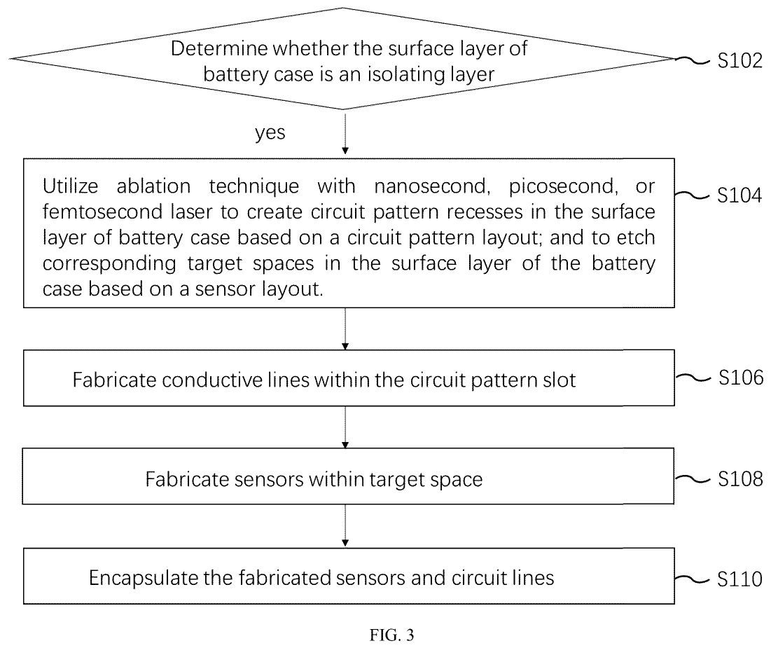

In order to further reduce the volume occupied by the sensor, so that the whole volume of the sensor and the cell body could be smaller, optionally, referring to FIG. 3, the step of S104 comprises:
S1041 utilizes an ablation process with nanosecond, picosecond, or femtosecond laser to create circuit pattern recesses in the surface layer of battery case based on a circuit pattern layout; and to etch corresponding target spaces in the surface layer of the battery case based on a sensor layout.

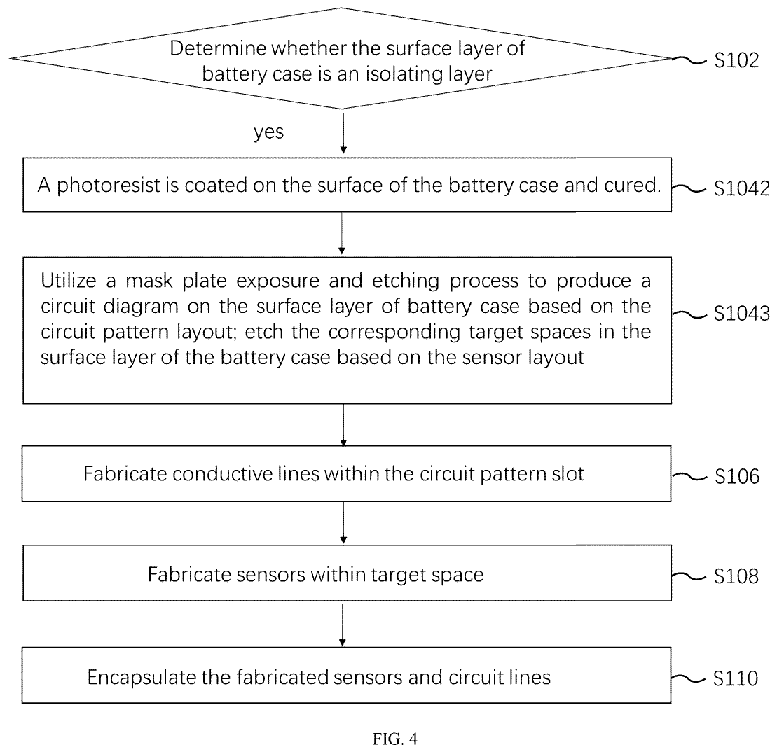

Alternatively, referring to FIG. 4, the stage of S104 include:
S1042, a photoresist is coated on the surface of the battery case and cured.
S1043, utilizing a mask plate exposure and etching process to produce a circuit diagram on the surface layer of battery case based on the circuit pattern layout; etch the corresponding target spaces in the surface layer of the battery case based on the sensor layout.

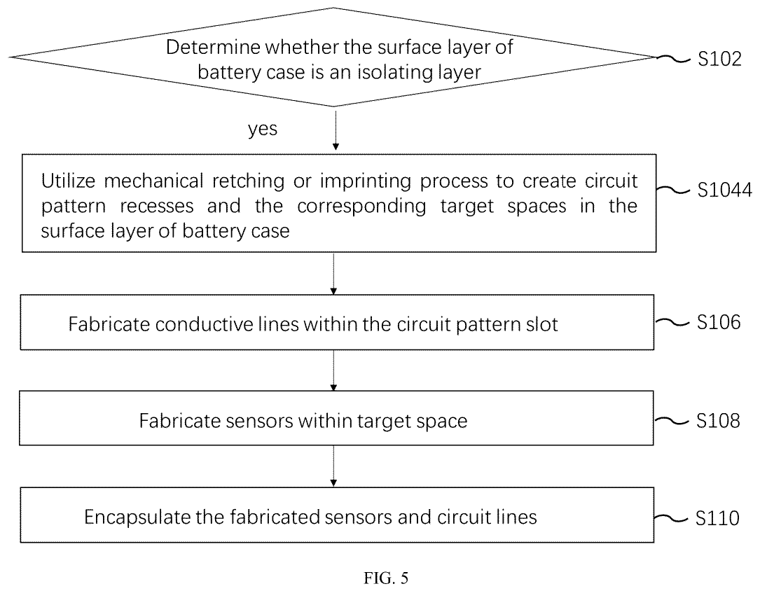

Alternatively, referring to FIG. 5, the steps of S104 include:
S1044, direct utilize mechanical retching or imprinting process to create circuit pattern recesses and the corresponding target spaces in the surface layer of battery case.

S106 includes:
Fabricate conductive lines within the circuit pattern slot.

S108 includes:
Making sensors in the target space.

Before making the conductive lines and sensors, grooves in the surface layer of the battery case, in order to make the conductive wires and sensors relatively lower than the surface plane of the battery case, which further reduce the size of battery and sensors.

As an implementation, circuit pattern recesses are formed directly on the surface layer of the battery case by using nanosecond or picosecond or femtosecond laser ablation, and the corresponding target space is etched out. Optionally, the line of circuit pattern recesses has a depth of 1 nanometer to 1 millimeter and a width of 1 nanometer to 10 millimeters.

Optionally, by setting this depth, subsequently in making the conductive line, the surface of the conductive line is changed to be with or equal to or below the surface of the cell.

As an alternative implementation, photoresist is coated on the battery surface and cured, followed by an exposure process through a mask plate, and finally deeply etched using a plasma dry etching method, where the exposure of the base circuitry and the sensor locations can be accomplished by either a single exposure or a multiple exposure process, to obtain circuit patterned recesses in the battery surface that have a thickness from 1 nanometer to 1 millimeter, and line widths from 1 nm to 10 mm of circuit patterned recesses in the cell surface.

In addition, it is noted that the types of battery sensors provided by the present application could be temperature, pressure, strain, gas, liquid, gravity, voltage, current or electromagnetic field sensors, etc., wherein some of the sensors are provide at the same layer as the base circuit recess, and could also be provided with a split layer, whereby the sensors are located above or below the base circuit recess.

For the case where the sensor is set in a different layer from the base circuit recess, laser drilling can be utilized with a hole diameter from 1 nanometer to 1 millimeter, allowing the sensor to be connected to the subsequent conductive circuitry to ensure proper functioning of the sensor.

And, the steps of S106 & S108 include:
After fabricating the conductive lines within the circuit pattern recess, a corresponding target space is then etched out; the conductive lines are fabricated while the corresponding target space is etched out, and the conductive lines are partially superimposed on the target space; or the conductive lines are fabricated while the corresponding target space is etched out and the target space is filled with colloid.

The present application can fabricate the circuit pattern recesses and sensors according to the above three sequences, and the present application does not make any limitation, wherein, when utilizing the mask plate for exposing and etching process to fabricate the circuit pattern recesses and sensors, if the conductive line is fabricated while etching out the corresponding target space and the conductive line is partially superimposed on the target space, it can be directly achieved by one exposure. When the conductive lines are made in the circuit pattern recess and then etch out the corresponding target space, or when the conductive line is made at the same time as the corresponding target space is etched and the target space is filled with colloid, this can be realized by a multiple-exposure process.

To fabricate the conductive lines, it can also be achieved in either of the following processes:

As the first realizing process, S106 includes:

Utilize the vacuum plasma sputtering technique, the plasma hit the metal target to form a metal vaporization for coating, and the mask layer is used to plate conductive lines with layout pattern on the surface layer of battery case.

Wherein, a vacuum plasma sputtering method can be used, the plasma hit on one or multi of copper target, gold target, titanium target, iron target, nickel target, lead target, etc. to form one or several layers of coating, result the conductive line with a thickness from 1 nanometer to 1 millimeter.

It should be mentioned that if the method of ablation with nanoseconds or picoseconds or femtoseconds laser is directly utilized to make circuit pattern recesses, it is necessary to utilize a mask to cover the surface area out of the circuit pattern recesses, in order to prevent the connection of conductive lines between the different recesses, which can lead to a short-circuiting of the sensors.

If photoresist is utilized to make circuit pattern recesses when fabricating the circuit pattern, the photoresist can be functionalized as a mask layer at the same time when fabricating the conductive lines, thus eliminating the need for an additional mask layer and reducing the production process.

As the second realizing process, S106 includes:

A conductive line is fabricated on the surface layer of battery case using metal ion solution injection or by a process of inkjet printing, dispensing, scraping, and (optionally utilizing a mask layer).

Wherein, using metal ion solution for injecting or by a process of inkjet printing, dispensing, or squeegee coating (optionally with a mask layer) method to form a conductive line from 1 nanometer to 1 millimeter on the surface of the circuit pattern recesses and the inner wall of the holes in the surface layer of battery case. Optionally, it is possible to use metal ions (one or mixed of copper ions, gold ions, titanium ions, iron ions, nickel ions, lead ions, etc.) cleaning program to etch in the circuit pattern recess for the surface and the inner wall of the holes for the activation before present process carried out, and can be coupled with the ion-plating process to increase the thickness of the circuit pattern recess and the holes within the conductive line, hereinafter not to be limited.

After fabricating the conductive line, the mask layer and the photoresist layer can be removed, and the sensor can be fabricated on the surface layer of battery case based on the sensor layout, wherein the sensor is connected to the conductive line.

It should be noted that the sensor made via inkjet printing, dispensing, and squeegee coating process of the present application, means that the raw materials are formulated into a solution for inkjet printing, dispensing, and squeegee coating, and then the solution is naturally volatilized or subjected to a baking lower than 200° C.

Finally, the base circuit and some of the sensors are encapsulated with polymer composite.

Wherein, in performing the encapsulation, S110 comprises:
The liquid state separating material is brushed onto the surface of the conductive line and the sensor to form a solid isolating layer.

In order to make encapsulation more convenient, this application uses liquid material for brushing, and after the liquid material is cured, a solid isolating layer is formed.

It is to be noted that the sensors described in the present application include but are not limited to liquid sensor, gas sensor, temperature sensors, strain sensors, stress sensors, electromagnetic, acceleration sensors, and gravity sensors.

On this basis, the connection between sensor and conductive line described in present application, referring that the conductive line is directly or indirectly connected to the sensor, for example, the electrode is the sensor for the liquid sensor, which connected to the circuit, but the two electrodes are not connected, relying on the formation of an electrical potential between the two separated distinct electrodes after the liquid has traveled in the system. So that this portion is not connected, and the sensor is indirectly connected to the conductive circuit.

In addition, when the sensor is a liquid sensor, the method further comprises, prior to the step of fabricating the sensor on the surface layer of battery case based on the sensor layout:
Laser drilling is utilized to drill holes according to the sensor layout;
The step of encapsulating the fabricated sensor as well as the conductive line includes:

A barrier layer is mounted on the surface of sensor which directly works as a surface encapsulation layer, wherein the barrier layer consists of a hydrophobic pro-electrolyte material.

By this setup, the leakage of electrolyte can be accurately detected when the leaked electrolyte flow into the space where the sensor is located. If water or other liquid flows into the barrier layer, the hydrophobic and electrolyte-friendly barrier layer is capable to block water flowing into the space where the sensor is located.

Also, when the sensor is a gas sensor, the step of encapsulating the surface layer of battery case after fabrication includes:

A barrier layer is mounted on the surface of sensor directly as a surface encapsulation layer, wherein the barrier layer is fabricated by a hydrophobic porous material.

In addition, for the conductive lines and sensors more closely fit with the surface layer of battery case, as an implementation, the method before S106 also includes:
S105, the polymer transition layer is fabricated based on the base circuit layout and the sensor layout.

On this basis, S106 comprises:
Fabrication of conductive lines based on transition layers;
S108 includes:

Making sensors based on transition layers.

Optionally, a small amount of metal ions may be added as a seed, and then grown as a polymer transition layer.

It is to be noted that in an optional realization, depending on the underlying circuit layout with the sensor layout, the polymer transition layer is grown at fixed sites on the surface of the battery case. As an alternative realization, it is also possible to grow the polymer transition layer throughout both the base circuit layout and the sensor layout, and then fabricate conductive circuits or sensors on the transition layer.

It is also noted that optionally, before the process S105, it is also possible to determine whether the adhesion between the conductive lines, the sensors, and the surface layer of the battery case is less than a threshold value, and if it is, then proceed step S105, and if it is not, then the conductive lines and the sensors are fabricated directly without the need to fabricate the transition layer. Wherein, the judgment for the adhesion degree between the conductive line, the sensor, and the surface layer of battery case can be determined by the material of the conductive line, the sensor, and the surface layer of battery case, or evaluate the degree of adhesion via experiment.

Of course, in one possible realizing process, it is also possible to directly make the polymer transition layer, there is no limitation herein.

Through these mentioned implementations, even in the case of poor adhesion between the conductive lines, sensors and the surface layer of battery case, it is possible to achieve a tight fit between the subsequently fabricated conductive lines, sensors and the surface layer of battery case by the transition layer, which is more effective.

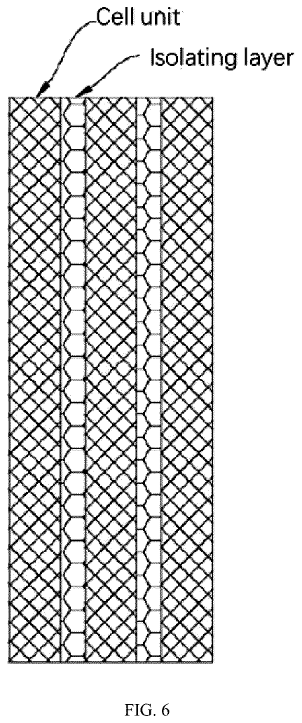

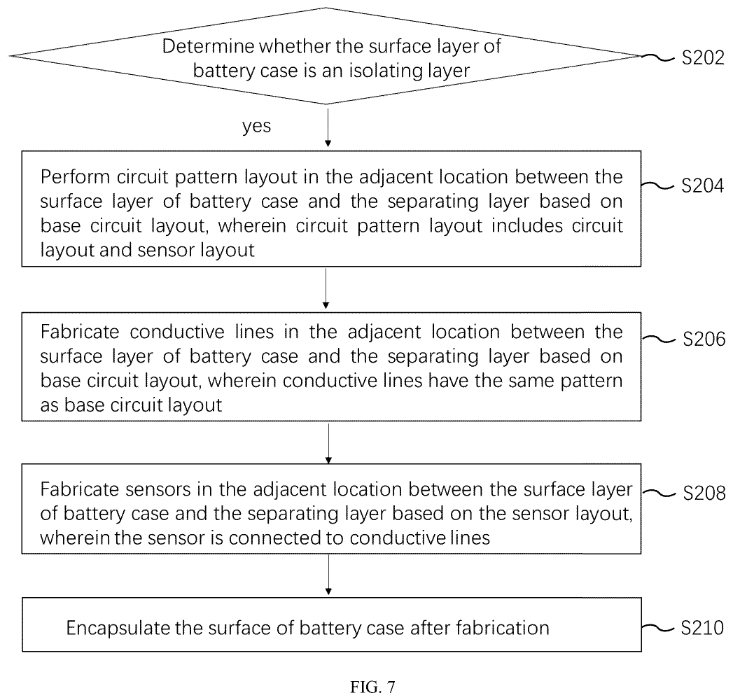

In addition, as another optional implementation for present application, the present application also provides another battery sensor fabrication method, which applied to fabricate sensor on battery pack, as shown in FIG. 6, wherein the battery package includes a plurality of cell units, and a separating layer is provided between two adjacent cell units; wherein the separating layer could be used for insulating, or for a thermal conductivity or insulation function, which is not limited herein. Referring to FIG. 7, the method comprises:
S202, determining whether the surface layer of battery is insulating layer; if so, performing S204.
S204, a circuit pattern layout is performed at a location where the surface layer of battery case is adjacent to the separating layer, wherein the circuit pattern layout includes a base circuit layout and a sensor layout;
S206 fabricates conductive lines in the surface layer of battery case which adjacent to the separating layer based on the underlying circuit layout, wherein the conductive lines have the same pattern as the circuit pattern;
S208, sensors are made in the surface layer of battery case which adjacent to the separating layer based on the sensor layout, wherein the sensors are connected to the conductive lines;
S210, encapsulate the surface of the fabricated battery case.

In this implementation, the conductive lines and sensors can be set to a location between the surface layer of battery case and the separating layer, making it possible to not occupy additional space in the whole system, and to be smaller and lighter in mass.

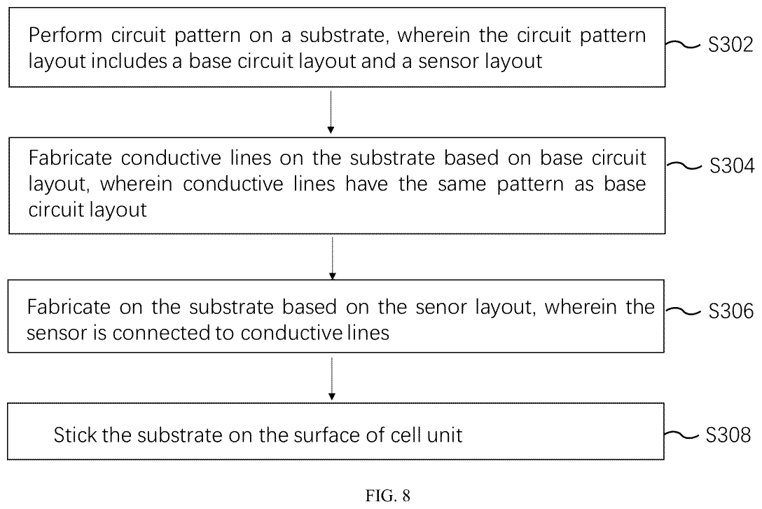

In another optional implementation, the battery sensor fabrication method is applied to fabricate a sensor on a battery package, the battery package comprising cell units, the cell units further comprising a substrate; referring to FIG. 8, the method comprises:
S302, a circuit pattern layout is performed on a substrate, wherein the circuit pattern layout includes a base circuit layout and a sensor layout.
S304, conductive lines are fabricated on the substrate based on the underlying circuit layout, wherein the conductive lines have the same pattern as the circuit pattern.
S306, a sensor is fabricated on the substrate based on the sensor layout, wherein the sensor is positioned in the same location as the sensor layout and the sensor is connected to the conductive line.
S308, the substrate is sticked to the surface of the cell unit.

Wherein, the substrate described in the present application can be a polymer material substrate or a composite material substrate, and is not limited herein. Moreover, as one implementation, after making sensors and conductive lines on the substrate, the substrate can be sticked to the cell unit, and thus the substrate can work as an isolating layer; as another implementation, after the substrate is sticked to the cell unit, an isolating layer can be added to the surface layer of the substrate again.

In summary, the present application provides a method for making battery sensor, firstly, when the surface layer of the battery case is insulating, a circuit pattern layout is carried out in the surface layer of the battery case, wherein the circuit pattern layout comprises a base circuit layout and a sensor layout; conductive line is fabricated in the surface layer of the battery case based on the base circuit layout, wherein the pattern of the conductive line is the same as that of the circuit pattern; the sensor is fabricated in the surface layer of the battery case based on the sensor layout sensor, wherein the sensor is the same as the sensor layout; and encapsulating the sensor and the conductive lines after the fabrication. Since the battery sensor fabrication method provided in present application makes sensor directly on the surface layer of battery case, the sensor is in close contact with the cell, and it has higher accuracy when detecting the battery state, and can determine the battery state more accurately with the battery management system. In addition, since the layout on the surface layer of battery case is directly made using the microfabrication process, the occupied space is reduced and does not significantly increase the size of the battery.

The foregoing is only a preferred embodiment of the present application and is not used to limit present application, which is subject to various changes and variations for the technicians in this research field. Any modifications, equivalent substitutions, improvements, etc. made within the spirit and principles of this application shall be included in the scope of protection.

For the technicians in this research field, it is apparent that the present application is not limited to the details of the above exemplary embodiments, and that it is capable of being realized in other specific forms without departing from the spirit or essential features of present application. Accordingly, the embodiments are to be regarded as exemplary and non-limiting from any point of view, and the scope of present application is limited by the appended claims but not by the foregoing description, and therefore intends to include all variations that fall within the meaning and scope of equivalent elements of the claims in present application. Any accompany marks in the claims should not be regarded as a limitation of the claims to which it relates.

What is claimed is:

1. A method of making a battery sensor, comprising:
when a surface layer of battery case is insulated, directly designing a circuit pattern layout on the surface layer of battery case, wherein the circuit pattern layout comprises a base circuit layout and a sensor layout;
making conductive lines in the surface layer of battery case based on the base circuit layout, wherein the conductive lines have the same pattern as the base circuit layout;
performing an inkjet printing, dispensing, and squeegee coating process on the surface layer of battery case based on the sensor layout, wherein a sensor is positioned in the same location as the sensor layout and the sensor is connected to the conductive line.

2. The method of making the battery sensor according to claim 1, wherein prior to the step of making the conductive lines in the surface layer of battery case based on the base circuit layout, the method further comprises:
directly utilizing ablation technique with nanosecond, picosecond or femtosecond laser, or a process of coating the surface layer of battery case with light-absorbing material and utilizing nanosecond, picosecond or femtosecond laser for ablation, or a process of exposing and etching a masked version on the surface layer of battery case, or a process of covering the surface layer of battery case with a photoresist and utilizing a process of exposure and etching a masked version of the surface layer of battery case, or a process of directly utilizing a process of mechanical etching or imprinting, making circuit pattern recesses based on the circuit pattern layout on the surface layer of battery case;
etching a corresponding target space on the surface layer of battery case according to the sensor layout;
the step of making the conductive lines in the surface layer of battery case based on the base circuit layout comprises: making the conductive lines in the circuit pattern recesses;
the step of making a sensor in the surface layer of battery case based on the sensor layout comprises: making a sensor in target space.

3. The method of making the battery sensor according to claim 2, wherein the step of making the circuit pattern recess in the surface layer of battery case based on the circuit pattern layout; and etching a corresponding target space in the surface layer of battery case based on the sensor layout further comprises:
etching a corresponding target space after making the conductive lines within the circuit pattern recesses; or making the conductive lines while etching out a corresponding target space, and the conductive lines are partially overlaying with the target space; or making the conductive line while etching out a corresponding target space and filling the target space with colloid.

4. The method of making the battery sensor according to claim 1, wherein prior to the step of making the conductive lines in the surface layer of battery case based on the base circuit layout, the method further comprises:
when the surface layer of battery case is conducting, grooving in the surface layer of battery case to form a slot;
depositing an insulating layer on a bottom of the slot; circuit pattern layout on insulating layer, wherein the circuit pattern layout comprises a base circuit layout with a sensor layout; or
making the insulating layer on the surface layer of battery case; the circuit pattern layout on the insulating layer, wherein the circuit pattern layout comprises the base circuit layout with the sensor layout.

5. The method of making the battery sensor according to claim 1, wherein the step of making the conductive lines in the surface layer of battery case based on the base circuit layout further comprises:
configuring a vacuum plasma sputtering process, the electrically conductive lines are fabricated in the surface layer of battery case according to a pattern of mask.

6. The method of making the battery sensor according to claim 1, wherein the step of making the conductive lines in the surface layer of battery case based on the base circuit layout comprises:
the conductive lines on the surface layer of battery case are made via inkjet printing, or dispensing, or screen-printing process with metal-ion solution; or a vapor depositing process with a circuit pattern mask to plate the conductive lines on the surface layer of battery case.

7. The method of making the battery sensor according to claim 1, wherein after the step of making the sensor on the surface layer of battery case based on the sensor layout, the method further comprises:
a liquid state barrier material is coated onto surface layer of conductive lines and sensors to form a packaging layer.

8. The method of making the battery sensor according to claim 1, wherein sensors comprise liquid sensor and gas sensor, and prior to the step of making the sensor in the surface layer of battery case based on the sensor layout, the method further comprises:
utilizing laser to drill holes in accordance with the sensor layout, wherein the sensors are located in the same position as the sensor layout; after the step of making the sensor in the surface layer of battery case based on the sensor layout, the method further comprises:
directly carrying out encapsulation on a surface of sensor; or directly configuring surface layer of a multilayer sensor as an encapsulation layer; the liquid sensor is configured for electrolyte leakage monitoring, whereas a surface barrier layer of the liquid sensor is made of hydrophobic pro-electrolyte material; the gas sensor is configured for gas leakage monitoring, and a surface barrier layer of the gas sensor is made of hydrophobic porous material.

9. The method of making the battery sensor according to claim 1, wherein prior to the step of making the conductive lines in the surface layer of battery case based on the base circuit layout, the method further comprises:
making a polymer transition layer based on the base circuit layout and the sensor layout;
the step of making the conductive lines in the surface layer of battery case based on the base circuit layout comprises: making the conductive lines based on the polymer transition layer;
the step of making the sensor in the surface layer of battery case based on the sensor layout comprises: making the sensor based on the polymer transition layer.

10. A method of making a battery sensor, comprising utilizing sensor in battery package, wherein the battery package comprises a plurality of battery units with a separating layer provided between two adjacent battery units; and the method comprises:
when the surface layer of battery case is insulating, carrying out a circuit pattern layout in the surface layer of battery case adjacent to the separating layer, wherein the circuit pattern layout comprises a base circuit layout and a sensor layout;
making conductive lines in the surface layer of battery case adjacent to the separating layer based on the base circuit layout, wherein the conductive lines have the same pattern as the base circuit layout and the sensor is connected to conductive lines;
performing an inkjet printing, or dispensing, or screen-printing process in the surface layer of battery case adjacent to the separating layer to make the sensor based on the sensor layout, wherein the sensor is located in the same position as the sensor layout.

11. A method of making a battery sensor, comprising utilizing sensor in battery package, wherein battery package comprises a plurality of battery units and substrate, and the method comprises:
performing a circuit pattern layout on the substrate, wherein the circuit pattern layout comprises a base circuit layout with a sensor layout;
making conductive lines on the substrate based on the base circuit layout, wherein the conductive lines have the same pattern as the base circuit layout and the sensor is connected to the conductive lines;
performing an inkjet printing, or dispensing, or screen printing process on the substrate to make the sensor based on the sensor layout, wherein the sensor is located in the same position as the sensor layout;
affixing the substrate to a surface of the battery unit.
